(19) United States
(12) Patent Application Publication
(10) Pub. No.: US 2005/0141205 A1
(43) Pub. Date: Jun. 30, 2005

(54) Insulating package structure

(76) Inventor: Rex Lin, Taipei Hsien (TW)

Correspondence Address: Rex Lin, 235 Chung-Ho, Box 8-24, Taipei, TW

(21) Appl. No.: 11/012,757

(22) Filed: Dec. 16, 2004

(30) Foreign Application Priority Data
Dec. 24, 2003 (CN) 200320130335.2

(51) Int. Cl. H05K 5/00

(52) U.S. Cl. 361/730

(57) ABSTRACT

An insulating package structure comprises at least one coil having a winding; each of two ends of the winding being connected to a conductive terminal; and an insulating package casing for packaging the coil and parts of the conductive terminals; a part of each conductive terminal not enclosed by the insulating package casing being exposed out of a bottom layer of the insulating package casing so as to be connected to a circuit board.

### FIELD OF THE INVENTION

The present invention relates to an insulating package structure, and in particular to an insulating package structure, wherein an insulating package casing has a larger space for receiving a coil, for example a transformer, while the area of the circuit board occupied by the insulating package casing is not enlarged so that a larger coil can be received.

### BACKGROUND OF THE INVENTION

With reference to FIG. 1, a prior art insulating package casing is illustrated. The conductive terminals 11 are exposed out from the lateral sides 12, 13 of the insulating package casing 10. Then each conductive terminals 11 is bended and then extends towards the circuit board by a bottom side of the conductive terminal 30. However the exposed portions of the conductive terminals will extend the area of the circuit board occupied by the insulating package casing. This is not beneficial for the design since the area of the circuit board is finite, many components must be installed on the circuit and thus it is advantageous to make any element occupy only a small area so that more elements can be installed on the circuit board, while this design waste a great area of the circuit board. Furthermore, this also causes that the coil, such as a transformer, cannot be too larger to be used on the circuit board.

### SUMMARY OF THE INVENTION

Accordingly, the primary object of the present invention is to provide an insulating package structure, wherein an insulating package casing has a larger space for receiving a coil, for example a transformer, while the area of the circuit board occupied by the insulating package casing is not enlarged so that a larger coil can be received.

To achieve above objects, the present invention provides an insulating package structure. The structure comprises at least one coil having a winding; each of two ends of the winding being connected to a conductive terminal; and an insulating package casing for packaging the coil and parts of the conductive terminals; a parts of each conductive terminal not enclosed by the insulating package casing being exposed out of a bottom layer of the insulating package casing so as to be connected to a circuit board.

The various objects and advantages of the present invention will be more readily understood from the following detailed description when read in conjunction with the appended drawing.

### BRIEF DESCRIPTION OF THE DRAWINGS

FIG. 1 is a perspective view of the prior art.

FIG. 2 is a structural view of the present invention.

FIG. 3 is an exploded cross sectional view of the present invention.

FIG. 4 is cross sectional views showing the contrast of the present invention with respect to the prior art.

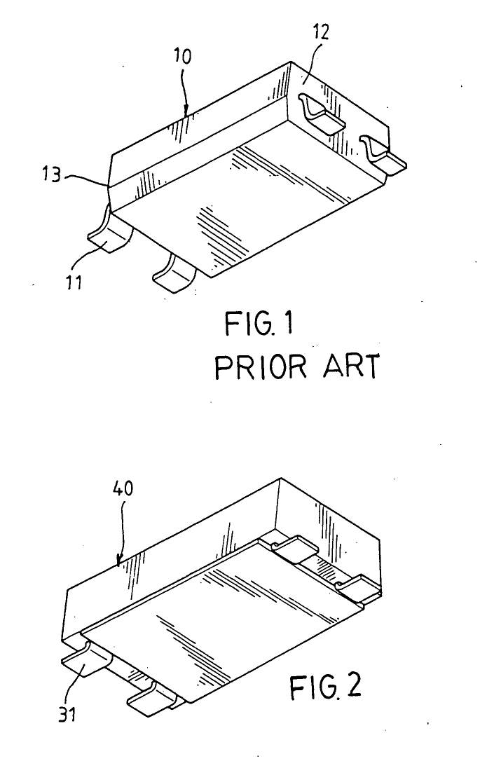

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

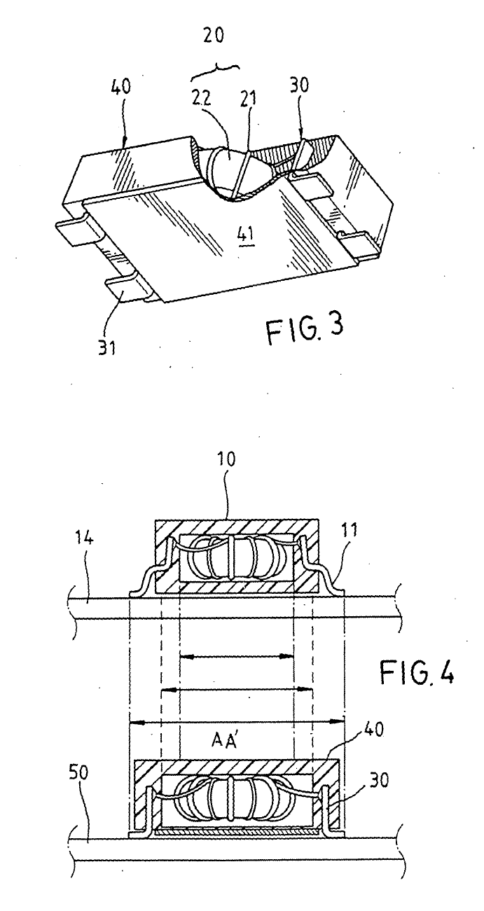

Referring to FIGS. 2 and 3, the structure of the present invention is illustrated. The present invention has the following elements.

At least one coil 20 is formed, for example as illustrated in FIG. 2, by a winding 21 winding around an iron core 22. Each of two ends of the winding 21 is connected to a conductive terminal 30.

An insulating package casing 40 serves for packaging the coil 20 and parts of the conductive terminals 30. A part of each conductive terminal 30 not enclosed by the insulating package casing 40 is exposed out of a bottom layer 41 of the insulating package casing 40 so as to be connected to a circuit board 50, as shown in FIG. 4 (the connection is known in the prior art). Thereby a larger coil 20 can be received within the insulating package casing 40.

Referring to FIG. 4, the upper side of the FIG. 4 shows a prior art for packaging a small transformer. In the lower side of FIG. 4 shows a packaging way according to the present invention. These two packages occupy the same area AA′ in the circuit board 50. In the prior art, the conductive terminals are extended from a middle part of the lateral sides of the insulating package casing, by the conductive terminals 30 are bended in the lateral side as a ladder shape. However in the present invention, each conductive terminal 30 of the present invention is exposed from the bottom layer of the insulating package casing and thus extends out. Thereby the insulating package casing may occupy the whole area AA′. Thereby it is larger that the prior art.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. An insulating package structure comprising:
at least one coil having a winding; each of two ends of the winding being connected to a conductive terminal; and
an insulating package casing for packaging the coil and parts of the conductive terminals; a parts of each conductive terminal not enclosed by the insulating package casing being exposed out of a bottom layer of the insulating package casing so as to be connected to a circuit board.
